(19) United States
(12) Patent Application Publication
(10) Pub. No.: US 2014/0034242 A1
(43) Pub. Date: Feb. 6, 2014

(54) EDGE RING ASSEMBLY FOR PLASMA PROCESSING CHAMBER AND METHOD OF MANUFACTURE THEREOF

(71) Applicants: Sanket P. Sant, Fremont, CA (US); Robert Griffith O'Neill, Fremont, CA (US)

(72) Inventors: Sanket P. Sant, Fremont, CA (US); Robert Griffith O'Neill, Fremont, CA (US)

(73) Assignee: Lam Research Corporation, Fremont, CA (US)

(21) Appl. No.: 13/562,675

(22) Filed: Jul. 31, 2012

(51) Int. Cl. H01L 21/3065; B23P 25/00

(52) U.S. Cl. 156/345.51; 29/458

(57) ABSTRACT

A two piece edge ring assembly is configured to surround a semiconductor substrate in a plasma processing chamber wherein plasma is generated and used to process the semiconductor substrate. The edge ring assembly comprises upper and lower rings which have an outer protective coating. The upper and lower rings are configured such that the upper ring is supported on an outer portion of the upper surface of the lower ring and the protective coatings are on plasma exposed surfaces of the upper and lower rings.

### FIELD OF THE INVENTION

The present invention relates to an edge ring assembly for use in a plasma processing chamber.

### BACKGROUND

Plasma processing apparatuses are used to process semiconductor substrates by techniques including etching, physical vapor deposition (PVD), chemical vapor deposition (CVD), and resist removal. One type of plasma processing apparatus used in plasma processing includes a reaction chamber containing top and bottom electrodes. A radio frequency (RF) power is applied between the electrodes to excite a process gas into a plasma for processing semiconductor substrates in the reaction chamber.

One challenge facing designers of plasma processing chambers is that the plasma etch conditions create significant ion bombardment of the surfaces of the processing chamber that are exposed to the plasma. This ion bombardment, combined with plasma chemistries and/or etch byproducts, can produce significant erosion, corrosion and corrosion-erosion of the plasma-exposed surfaces of the processing chamber. Another challenge is to control etch rate uniformity across a semiconductor substrate (e.g., silicon substrate), in particular, to make the etch rate at the center of the substrate equal to the etch rate at the edge. To alleviate such nonuniformities, an edge ring and an underlying support ring have been implemented fitting around the substrate. The edge ring is a consumable part and requires regular cleaning or replacement. It is desirable to extend the lifetime of the edge ring in order to increase mean time between cleaning or replacement and to decrease the cost of ownership. An edge ring assembly with extended RF lifetime is described herein.

### SUMMARY

Disclosed herein is an edge ring assembly configured to surround a semiconductor substrate in a plasma processing chamber wherein plasma is generated and used to process the semiconductor substrate. The plasma processing chamber comprises a substrate support which has a vertical sidewall extending between an outwardly extending annular support surface and a circular substrate support surface. The substrate support is configured such that the semiconductor substrate is supported on the substrate support surface and an overhanging edge of the semiconductor substrate extends beyond the vertical sidewall. A support ring is configured to be supported around the substrate support and the edge ring assembly is at least partially supported above the support ring. The edge ring assembly comprises a lower ring having a protective outer coating at least on a plasma exposed portion of an inner surface and an upper surface of the lower ring, and an upper ring having a protective outer coating at least on a plasma exposed portion of an inner surface and an upper surface of the upper ring. The lower ring has a lower surface configured to be supported around the substrate support, the inner surface extending upwardly from an inner periphery of the lower surface and configured to surround the vertical sidewall, the upper surface extending outwardly from the inner surface, configured to underlie the overhanging edge of the semiconductor substrate, and an outer surface extending downwardly from an outer periphery of the upper surface. The upper ring has a lower surface configured to be supported on an outer portion of the upper surface of the lower ring, the inner surface extending upwardly from an inner periphery of the lower surface and configured to surround the semiconductor substrate, the upper surface extending outwardly from the inner surface, and an outer surface extending downwardly from an outer periphery of the upper surface. The upper ring is located on an outer portion of the upper surface of the lower ring.

Also disclosed herein is a method of making an edge ring assembly for use in a plasma processing chamber. The method comprises (a) coating upper and inner surfaces of the upper ring with a protective outer coating, (b) coating upper and inner surfaces of the lower ring with a protective outer coating, and (c) assembling the rings such that the upper ring covers only an outer portion of the upper surface of the lower ring, and the protective coatings are on plasma exposed portions of the upper and lower rings.

### BRIEF DESCRIPTION OF THE DRAWING FIGURES

FIG. 1 illustrates a portion of an embodiment of a showerhead electrode assembly and a substrate support for a plasma processing apparatus wherein embodiments presented herein may be practiced.

FIG. 2 illustrates a cross section of an embodiment of an edge ring assembly.

FIGS. 3A-D illustrate cross sections of preferred embodiments of an edge ring assembly.

FIGS. 4A, B illustrate cross sections of an alternate preferred embodiment of an edge ring assembly.

FIG. 5 illustrates a cross section of an alternate preferred embodiment of an edge ring assembly.

### DETAILED DESCRIPTION

As integrated circuit devices continue to shrink in both their physical size and their operating voltages, their associated manufacturing yields become more susceptible to particle and metallic impurity contamination. Consequently, fabricating integrated circuit devices having smaller physical sizes requires that the level of particulate and metal contamination be less than previously considered to be acceptable.

The manufacturing of the integrated circuit devices includes the use of plasma processing chambers. A plasma processing chamber may be configured to etch selected layers of a semiconductor substrate. Such a processing chamber is configured to receive process gases while a radio frequency (RF) power is applied to one or more electrodes in the processing chamber. The pressure inside the processing chamber is also controlled for the particular process. Upon applying the desired RF power to the electrode(s), the process gases in the chamber are activated such that a plasma is created. The plasma is thus generated to perform desired etching of selected layers of the semiconductor substrate.

One challenge facing designers of plasma processing chambers is that the plasma etch conditions create significant ion bombardment of the surfaces of the processing chamber that are exposed to the plasma. This ion bombardment, combined with plasma chemistries and/or etch byproducts, can produce significant erosion, corrosion and corrosion-erosion of the plasma-exposed surfaces of the processing chamber. As a result, surface materials are removed by physical and/or chemical attack, including erosion, corrosion and/or corrosion-erosion. This attack causes problems including short part lifetimes, increased parts costs, particulate contamination, on-substrate transition metal contamination and process drift. Parts with relatively short lifetimes are commonly referred to as consumables. Short lifetimes of consumable parts increase the cost of ownership.

Another challenge is to control etch rate uniformity across a semiconductor substrate (e.g., silicon substrate), in particular, to make the etch rate at the center of the substrate equal to the etch rate at the edge. Therefore, substrate boundary conditions are preferably designed for achieving uniformity across the substrate in regard to parameters such as process gas composition, process gas pressure, substrate temperature, RF power, and plasma density.

Some plasma processing chambers are designed to have RF power applied to a powered electrode underlying an electrostatic clamping electrode, both of which are incorporated in a substrate support that supports a semiconductor substrate undergoing plasma processing. However, because the outer edge of the substrate may overhang the bottom electrode and/or the RF impedance path from the powered electrode through the electrostatic clamping electrode and substrate to the plasma can be different than the RF impedance path from an outer portion of the powered electrode to the plasma, a nonuniform plasma density which results at the edge of the substrate can lead to nonuniform processing of the substrate.

To alleviate such nonuniformities, an edge ring assembly and an underlying support ring, coupling ring and/or ground ring have been implemented fitting around the substrate support. Improved plasma uniformity can be achieved by providing an RF impedance path which is similar at the center and edge of a substrate undergoing plasma processing. The RF impedance path can be manipulated by choice of materials and/or dimensions of the support, coupling and/or ground ring. The support ring, coupling ring, and/or ground ring may be formed from a conductor, semiconductor, or dielectric material. In an embodiment the support ring, coupling ring, and/or ground ring may be formed from quartz or alumina.

The edge ring assembly shields the support ring, ground ring, and/or coupling ring from plasma attack. The edge ring assembly is a consumable part and requires regular cleaning or replacement. It is desirable to extend the lifetime of the edge ring assembly in order to increase mean time between cleaning or replacement and to decrease the cost of ownership, and to reduce possible wafer contamination from particles which may become loose during plasma processing of wafers. An edge ring assembly with extended RF lifetime and which reduces wafer contamination is described herein.

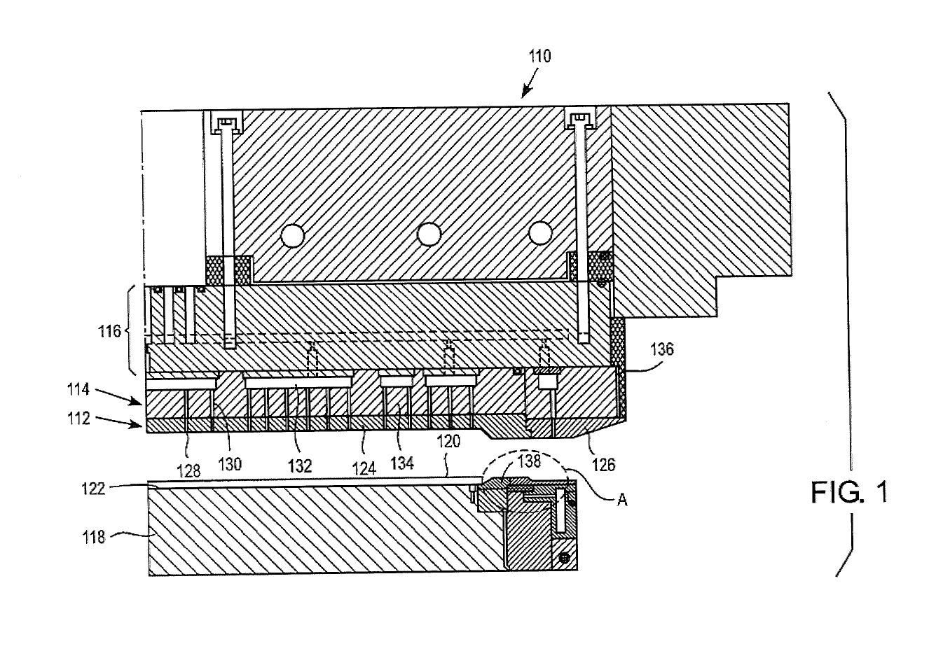

FIG. 1 illustrates an exemplary embodiment of a showerhead electrode assembly 110 for a plasma processing chamber in which semiconductor substrates, e.g., silicon substrates, are processed, wherein embodiments of the edge ring assembly discussed herein may be used. The showerhead electrode assembly 110 includes a showerhead electrode including a top electrode 112, a backing member 114 secured to the top electrode 112, and a thermal control plate 116. Details of such arrangements can be found in commonly-assigned U.S. Pat. Nos. 7,862,682, 7,854,820 and 7,125,500, incorporated herein by reference. A substrate support 118 (only a portion of which is shown in FIG. 1) including a bottom electrode and an electrostatic clamping electrode (e.g., electrostatic chuck) is positioned beneath the top electrode 112 in the plasma processing chamber. A substrate 120 subjected to plasma processing is electrostatically clamped on a substrate support surface 122 of the substrate support 118 (e.g., an electrostatic chuck).

In a capacitively coupled plasma processing chamber, a secondary ground may also be used in addition to the ground electrode. For example, the substrate support 118 can include a bottom electrode which is supplied RF energy at one or more frequencies and process gas can be supplied to the interior of the chamber through showerhead electrode 112 which is a grounded upper electrode. A secondary ground, located outwardly of the bottom electrode in the substrate support 118 can include an electrically grounded portion which extends generally in a plane containing the substrate 120 to be processed but separated from the substrate 120 by an edge ring assembly 138. The edge ring assembly 138 can be of electrically conductive or semiconductive material which becomes heated during plasma generation.

To reduce contamination of processed substrates, the edge ring assembly may be coated with a coating such as thermal sprayed yttria or aerosol deposited yttria. However, during thermal spraying or aerosol deposition, powder can accumulate on inner corners and lead to loose particles and wafer contamination during plasma processing of wafers.

For control of etch rate uniformity on substrate 120 and matching the etch rate at the center of the substrate to the etch rate at the substrate edge, substrate boundary conditions are preferably designed for assuring continuity across the substrate in regard to the chemical exposure of the substrate edge, process pressure, and RF field strength. In order to minimize substrate contamination, the edge ring assembly 138 is manufactured from a material compatible to the substrate itself. The material of the edge ring assembly 138 may be formed from silicon, silicon carbide, alumina and/or a composite of said materials. Preferably the edge ring assembly 138 will have a protective outer coating bonded to members of the edge ring assembly so as to increase corrosion and wear resistance of the edge ring assembly 138. Preferably, the outer coating will be a yttrium oxide spray coating. To avoid the problem of loose particles originating from the coating in geometric features such as inner corners, the edge ring is a two piece edge ring as described below.

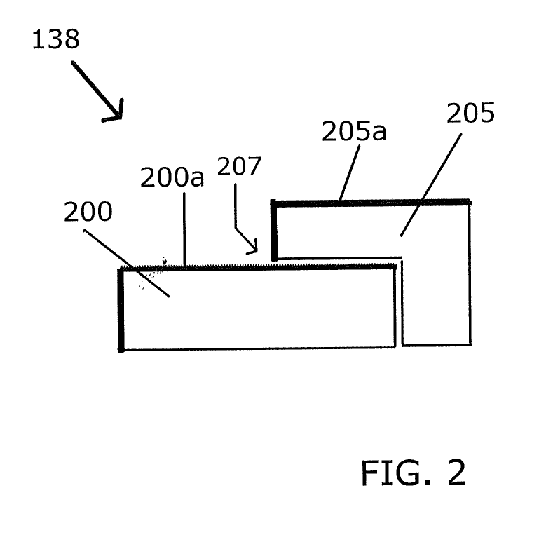

FIG. 2 illustrates a cross section of an embodiment of the edge ring assembly 138. The edge ring assembly 138 comprises a lower ring 200 and an upper ring 205. The lower and upper rings 200, 205 each have a protective outer coating 200a, 205a. The lower ring 200 may be rectangular in cross section, and the upper ring 205 may be L-shaped in cross section. In alternative embodiments, it should be appreciated that the lower ring 200 may be L-shaped in cross section. Additionally, it should be appreciated that the upper ring 205 may be rectangular in cross section. When assembled, the upper and lower rings form an inner corner at the joint 207 between the upper surface of the lower ring and the inner surface of the upper ring. At least the plasma exposed inner and upper surfaces of the rings can be coated with a protective coating such as yttria and when the parts are assembled, the coated surfaces form an inner corner without the particle problem exhibited by a one piece edge ring having a thermally sprayed coating on an inner corner.

Preferably, the upper and lower rings 205, 200 are each formed from alumina and each have a protective outer coating 205a, 200a. The protective outer coatings 200a, 205a preferably may be a yttrium oxide layer. In alternative embodiments the outer coating may be comprised of SiC, Si, SiO₂, ZrO₂, or Si₃N₄. Additionally, the protective outer coatings 200a, 205a may be applied by aerosol deposition (AD), chemical vapor deposition (CVD), physical vapor deposition (PVD), thermal spray coating, or atomic layer deposition (ALD). Preferably, the outer protective coatings 200a, 205a are applied by aerosol deposition. Aerosol deposition has been developed over the past 15 years to provide a film deposition technique which provides a manufacturing method for fabricating ceramic coatings of adequate thickness to fully encapsulate, while still remaining cost effect. The process typically requires a polishing step to eliminate loosely bonded particles on the surface, exposing the highly dense coating. This coating has recently been demonstrated to provide significant particle improvements over spray coatings. An exemplary aerosol deposition method may be found in U.S. Pat. No. 8,114,473 assigned to Toto, Ltd., which is incorporated herein by reference in its entirety.

Each ring 200, 205 has the protective coating 200a, 205a applied independently. In an embodiment, the protective coatings 200a, 205a are applied to all surfaces of the rings 200, 205. Preferably, the protective coatings 200a, 205a are applied only to plasma exposed surfaces of the lower and upper rings 200, 205. In a more preferred embodiment, the protective coatings 200a, 205a are not applied to mating surfaces of the lower ring 200 and the upper ring 205. However, the coating may be applied to one or both mating surfaces if desired.

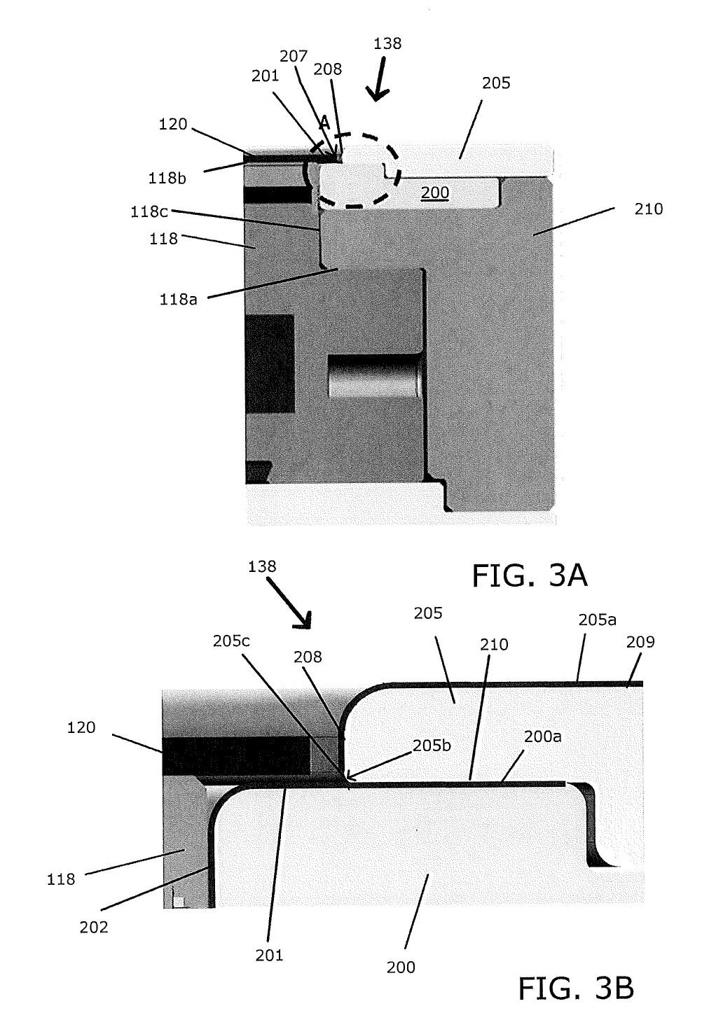

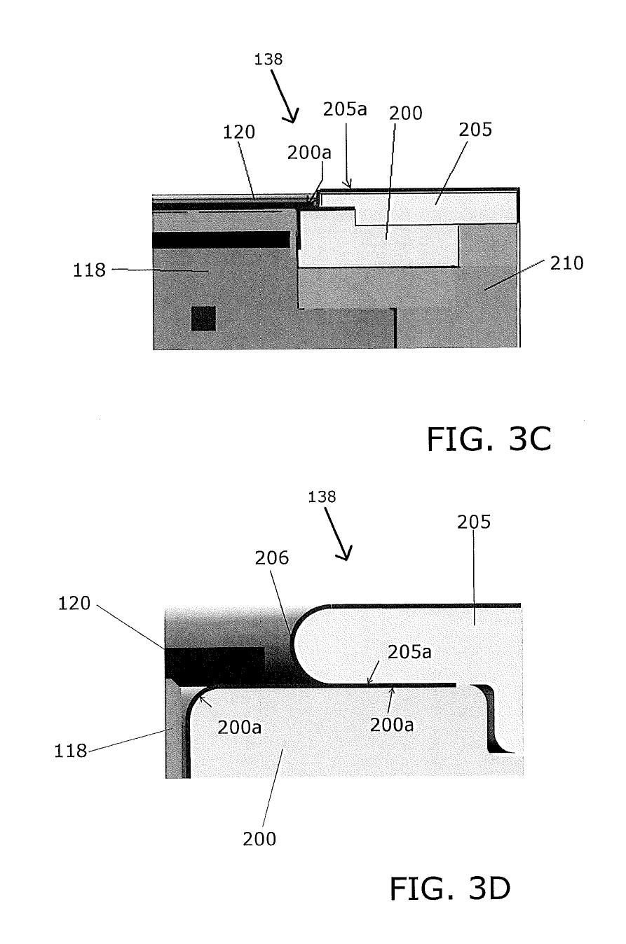

FIGS. 3A-D illustrate cross sections of a preferred embodiment of the edge ring assembly 138 for use in a plasma processing chamber. FIG. 3A illustrates the substrate support 118 comprising a vertical sidewall 118c extending between an outwardly extending annular support surface 118a and a circular substrate support surface 118b. The substrate support 118 may be configured to support the semiconductor substrate 120 on the substrate support surface 118b. The substrate 120 may have an overhanging edge which extends beyond the outer vertical sidewall of the substrate support 118. A support ring 210 may be supported on the annular support surface 118a of substrate support 118. In an embodiment, the edge ring assembly 138 may be supported on the support ring 210. The support ring 210 may be electrically grounded an in embodiment.

Preferably, the edge ring assembly 138 is comprised of a lower flanged ring 200 and an upper flanged ring 205 both of which are L-shaped in cross-section taken along a plane passing through a center axis of the rings. Preferably, the lower and upper rings 200, 205 are configured such that an inner portion of the upper surface 201 of the lower ring 200 and the inner surface 208 of the upper ring 205 form an inner corner 207. In an embodiment, the upper surface of the upper ring 205 may extend upwardly and outwardly such that the upper surface of the upper ring 205 forms a sloped (inclined) surface.

FIG. 3B illustrates a cross section of a preferred embodiment of the edge ring assembly 138 comprised of lower and upper rings 200, 205 which each have a respective protective outer coating 200a, 205a. The lower and upper rings 200, 205 preferably have rounded inner and outer corners and the coatings 200a, 205a are applied to flat surfaces and outer rounded corners of the rings 200, 205. In the FIG. 3B embodiment, the upper and lower rings have rounded corners (e.g., 0.04-0.05 inch radius rounded edges) between respective inner vertical surfaces 208, 202 and respective upper surfaces 209, 201 and smaller radius corners (e.g., 0.01 inch radius edge) at the bottom inner edge 205c of upper ring 205. Preferably, the respective protective coatings 200a, 205a are formed on respective lower and upper rings 200, 205, and the lower and upper rings 200, 205 are configured such that plasma exposed surfaces of the edge ring assembly 138 are coated. While not wishing to be bound by theory, it is believed that inner corners of bodies to be coated are less receptive to spray coatings such as thermal spray coatings and/or aerosol deposited coatings. Inner corners may be difficult to spray and may result in decreased wear and erosion resistance and an increase in loose particles during processing of substrates in the plasma processing chamber. Therefore, it is preferred that inner corners of the upper and lower rings 200, 205 not be coated with the respective protective outer coatings 200a, 205a. The upper ring 205 may include a small diameter radius at the corner 205c between inner surface 208 and bottom surface 210. The coating 205a may be absent at the corner 205c and form a coating gap 205b between the coating 200a and coating 205a. If present, it is preferred that the coating gap 205b is less than about 0.01 inch. More preferably, the coatings are applied such that there is no coating gap 205b.

The upper ring 205 can be L-shaped in cross-section with a height between about 0.05 inch and 0.5 inch. For example the upper ring can have a total height of about 0.15 inch at an outer periphery and a height of about 0.08 inch in the inner portion overlying bottom ring 200. The lower ring 200 may also be L-shaped in cross-section with a height between about 0.05 inch and 0.5 inch. For example the lower ring can have a total height of about 0.15 inch at an inner periphery and a height of about 0.08 inch at an outer periphery. The outer protective coatings 200a, 205a can have a thickness of 2 to 20 μm, preferably 5 to 15 μm.

FIG. 3C illustrates an alternate embodiment of the edge ring assembly 138 having the same configuration as illustrated in FIGS. 3A, B. However, in the alternate embodiment, the lower and upper rings 200, 205 have right-angled inner and outer corners.

FIG. 3D illustrates an alternate embodiment of the edge ring assembly 138 having the same configuration as illustrated in FIGS. 3A-C. However, in the alternate embodiment the upper ring 205 has a beveled inner surface 206. The radius of the beveled inner surface 206 can be between about 0.04 to about 0.045 inch. Furthermore, lower and upper rings 200, 205 comprise the protective outer coatings 200a, and 205a on an inner periphery of their respective mating surfaces.

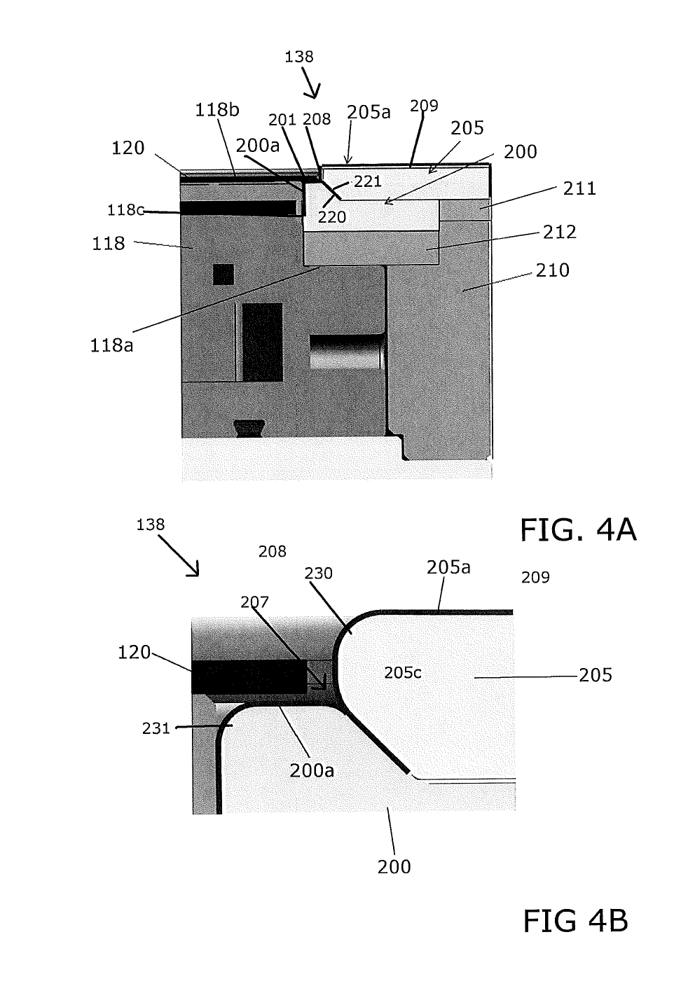

FIGS. 4A, B illustrate cross sections of an alternate preferred embodiment of the edge ring assembly 138 for use in a plasma processing chamber. FIG. 4A illustrates the substrate support 118 comprising a vertical sidewall 118c extending between an outwardly extending annular support surface 118a and a circular substrate support surface 118b. The substrate support 118 supports the semiconductor substrate 120 on the substrate support surface 118b such that the substrate 120 has an overhanging edge which extends beyond the vertical sidewall 118c of the substrate support 118. A portion of a coupling ring 212 may be supported on the annular support surface 118a of substrate support 118, while the remaining portion of coupling ring 212 may be supported on a surface of support ring 210.

Preferably, the edge ring assembly 138 is comprised of a lower ring 200 and an upper ring 205. The lower ring 200 may be supported by coupling ring 212, while the upper ring 205 may be partially supported by the lower ring 200 and partially supported by an outer coupling ring 211 which is supported on support ring 210. In an alternative embodiment the upper ring 205 may be partially supported by the support ring 210. In an alternate embodiment, the coupling rings 210 and 211 may be omitted, and the support ring 210 may be configured to support the edge ring assembly 138.

The lower ring 200 may have a generally L-shaped cross section with an inclined surface 220 extending outwardly and downwardly from an outer periphery of the exposed portion of the upper surface 201. The upper ring 205 may have a generally rectangular cross section with an inclined surface 221 mating with inclined surface 220 of the lower ring 200. Preferably, the lower and upper rings 200, 205 are configured such that mating surfaces of the lower and upper rings 200, 205 include horizontal and inclined surfaces which contact each other. The exposed upper surface of the lower ring and exposed inner surface of the upper ring form an inner step 207 (as illustrated in FIG. 4B). If desired, the upper surface 209 of the upper ring 205 may be sloped upwardly and outwardly.

FIG. 4B illustrates a cross section of a preferred embodiment of the edge ring assembly 138 comprised of lower and upper rings 200, 205 which each have a respective protective outer coating 200a, 205a. The lower and upper rings 200, 205 preferably have rounded inner and outer corners 230, 231 at upper inner peripheries thereof and the coatings 200a, 205a are applied to flat surfaces and outer rounded corners of the rings 200, 205. In the FIG. 4B embodiment, the upper ring 205 has a rounded corner (e.g., 0.04-0.05 inch radius) at the corner between the inner vertical surface 208 and the upper surface 209 and a larger radius corner at a corner 205c along the lower surface. Preferably, the respective protective coatings 200a, 205a are formed on respective lower and upper rings 200, 205 such that plasma exposed surfaces of the edge ring assembly 138 are coated. In an embodiment, one or more mating surfaces of rings 200, 205 may have the protective coatings 200a, 205a, and in an alternative embodiment the mating surfaces may be uncoated surfaces.

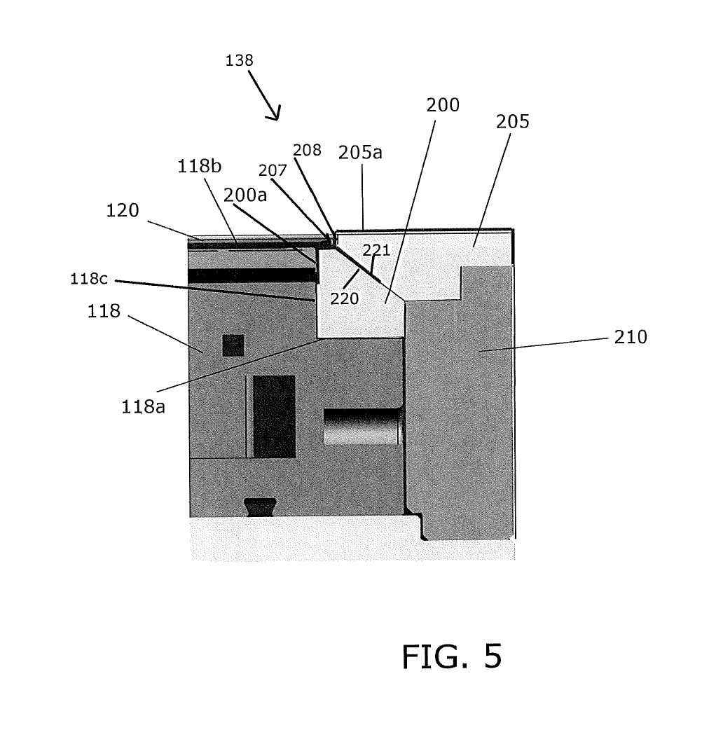

FIG. 5 illustrates a cross section of an alternate preferred embodiment of the edge ring assembly 138 for use in a plasma processing chamber. The substrate support 118 comprises a vertical sidewall 118c extending between an outwardly extending annular support surface 118a and a circular substrate support surface 118b. The substrate support 118 supports the semiconductor substrate 120 on the substrate support surface 118b such that an overhanging edge of the substrate extends beyond the vertical sidewall 118c of the substrate support 118. A support ring 210 may be configured to surround the substrate support 118, and the edge ring assembly 138 may be partially supported above the support ring 210 and partially supported on the substrate support surface 118a.

Preferably, the edge ring assembly 138 is comprised of a lower ring 200 and an upper ring 205. The lower ring 200 may have a generally rectangular shaped cross section with an inclined surface 220 extending outwardly and downwardly from an outer periphery of the exposed upper surface. The upper ring 205 may have a generally rectangular cross section with an inclined surface 221 extending downwardly and outwardly from an exposed inner surface 208. Additionally, the upper ring 205 may have a step along the lower surface extending from an outer portion of the lower surface to the outer surface. Preferably, the lower and upper rings 200, 205 are configured such that mating surfaces of the lower and upper rings 200, 205 are the inclined surfaces 220, 221. The lower and upper rings 200, 205 preferably form a step 207, forming a right angle, extending between the exposed upper surface of the lower ring 200 and the exposed inner surface of the upper ring 205. If desired, the upper surface of the upper ring 205 may be an inclined surface which extends upwardly and outwardly.

Additionally presented herein is a method of coating an edge ring assembly comprising upper and lower rings with a protective outer coating. The method comprises (a) coating upper and inner surfaces of the upper ring with a protective outer coating, (b) coating upper and inner surfaces of the lower ring with a protective outer coating, and (c) assembling the rings such that the upper ring covers only an outer portion of the upper surface of the lower ring. Preferably the protective outer coatings are applied to the plasma exposed surfaces of the upper and lower rings.

While the edge ring assembly has been described in detail with reference to specific embodiments thereof, it will be apparent to those skilled in the art that various changes and modifications can be made, and equivalents employed, without departing from the scope of the appended claims.

What is claimed is:

1. An edge ring assembly configured to surround a semiconductor substrate in a plasma processing chamber wherein plasma is generated and used to process the semiconductor substrate, the plasma processing chamber comprising a substrate support comprising a vertical sidewall extending between an outwardly extending annular support surface and a circular substrate support surface, the substrate support configured such that the semiconductor substrate is supported on the substrate support surface and an overhanging edge of the semiconductor substrate extends beyond the vertical sidewall; a support ring configured to be supported around the substrate support; and the edge ring assembly at least partially supported above the support ring, the edge ring assembly comprising:
a lower ring having a protective outer coating on at least a plasma exposed portion of an inner surface and an upper surface, the lower ring having a lower surface configured to be supported around the substrate support, the inner surface extending upwardly from an inner periphery of the lower surface and configured to surround the vertical sidewall, the upper surface extending outwardly from the inner surface, configured to underlie the overhanging edge of the semiconductor substrate and an outer surface extending downwardly from an outer periphery of the upper surface, wherein the protective; and
an upper ring having a protective outer coating on at least a plasma exposed portion of an inner surface and an upper surface, the upper ring having a lower surface configured to be supported on an outer portion of the upper surface of the lower ring, the inner surface extending upwardly from an inner periphery of the lower surface and configured to surround the semiconductor substrate, the upper surface extending outwardly from the inner surface, and an outer surface extending downwardly from an outer periphery of the upper surface wherein the upper ring is located on an outer portion of the upper surface of the lower ring.

2. The edge ring assembly of claim 1, wherein the upper ring is L-shaped in cross section and the lower ring is rectangular in cross section.

3. The edge ring assembly of claim 1, wherein the upper ring is L-shaped in cross section and the lower ring is L-shaped in cross section.

4. The edge ring assembly of claim 1, wherein the upper surface of the lower ring has vertically offset horizontal sections and the lower surface of the upper ring has vertically offset horizontal sections.

5. The edge ring assembly of claim 4, wherein the upper and lower rings have rounded corners having a radius between about 0.04 to 0.05 inch between each respective inner vertical surface and each upper surface and the upper ring has a rounded bottom corner having a radius of about 0.01 inch between the inner and lower surfaces.

6. The edge ring assembly of claim 5, wherein the bottom corner is not coated and forms a gap in the protective outer coatings, wherein the gap is less than about 0.01 inch.

7. The edge ring assembly of claim 4, wherein the bottom corner is coated with the protective outer coating.

8. The edge ring assembly of claim 1, wherein the upper and lower rings are formed from silicon carbide, silicon, or alumina.

9. The edge ring assembly of claim 1, wherein the protective outer coating is yttrium oxide, silicon carbide, silicon, silicon oxide, zirconium oxide, or silicon nitride.

10. The edge ring assembly of claim 1, wherein the protective outer coating is applied by aerosol deposition, chemical vapor deposition, physical vapor deposition, atomic layer deposition, or thermal spraying.

11. The edge ring assembly of claim 1, wherein the protective outer coating is not applied on mating surfaces of the upper and lower rings.

12. The edge ring assembly of claim 1, wherein the protective outer coating is applied on at least one mating surface of the upper and lower rings.

13. The edge ring assembly of claim 1, wherein mating surfaces of the upper and lower rings include horizontal and inclined surfaces, the lower surface of the upper ring including an inclined portion mating with an inclined portion of the upper surface of the lower ring.

14. The edge ring assembly of claim 1, wherein the upper and lower rings are configured such that an outer portion of the lower surface of the upper ring and the outer surface of the lower ring form a step.

15. The edge ring assembly of claim 1, wherein the upper ring has a step between the outer and lower surfaces thereof.

16. The edge ring assembly of claim 15, wherein the upper and lower rings are configured such that an outer portion of the lower surface of the upper ring and the outer surface of the lower ring form a step.

17. A method of making the edge ring assembly of claim 1, the method comprising:
coating inner and upper surfaces of the lower ring with the protective outer coating;
coating inner and upper surfaces of the upper ring with the protective outer coating; and
assembling the upper and lower rings such that at least a portion of the lower surface of the upper ring is on an outer portion of the upper surface of the lower ring.

18. The method of claim 17, wherein the protective outer coatings are yttrium oxide.

19. The method of claim 17, wherein the protective outer coatings are applied by aerosol deposition.

20. The method of claim 17, wherein the protective outer coatings are applied on at least one mating surface of the upper and the lower rings.
